(19) United States
(12) Patent Application Publication
(10) Pub. No.: US 2003/0228542 A1
(43) Pub. Date: Dec. 11, 2003

(54) Method and structure to reduce e-beam and magnetic material interactions

(75) Inventors: Michael Kevin Minor, Gibsonia, PA (US); Andrew Robert Eckert, Pittsburgh, PA (US); Xiaomin Yang, Sewickley, PA (US); Keith Robert Mountfield, Pittsburgh, PA (US)

Correspondence Address: Bryan H. Opalko, Esquire, Buchanan Ingersoll, P.C., One Oxford Centre, 20th Floor, 301 Grant Street, Pittsburgh, PA, 15219, US

(73) Assignee: Seagate Technology LLC, Scotts Valley, CA (US)

(21) Appl. No.: 10/280,828

(22) Filed: Oct. 25, 2002

Related U.S. Application Data
(60) Provisional application No. 60/386,773, filed on Jun. 6, 2002.

(51) Int. Cl. G03F 7/16; G03F 7/20; B21F 1/00; B21C 1/00; B21H 3/00; B21C 27/00; B32B 15/04; G03F 7/40; B32B 3/00; B32B 3/30; B22F 5/00; H01F 1/00; H01L 21/00

(52) U.S. Cl. 430/296; 428/577; 428/457; 428/694 TS; 428/694 TM; 428/601; 428/611; 438/3; 430/314; 430/319; 430/320

(57) ABSTRACT

A magnetic material structure is provided according to the present invention that is capable of being lithographically patterned for various uses, such as, but not limited to, magnetic read/write devices. The magnetic material structure includes a layer of magnetic material provided on a wafer or other substrate, a layer of non-magnetic material provided on top of the layer of magnetic material, and a layer of soft magnetic material provided on top of the layer of non-magnetic material. The magnetic material which is to be patterned will have a magnetic field component normal to a plane of the layer of magnetic material. To minimize the effect this normal magnetic field component will have on electrons as they impinge the structure surface during e-beam lithography, the soft magnetic material has a high-plane permeability sufficient to divert the normal magnetic field component of the magnetic material into a plane of the layer of soft magnetic material. By “bending” the normal magnetic field component into the plane of the soft magnetic material layer, interactions between the normal magnetic field component and the electron beam are reduced, and the e-beam offsets caused by such interactions are also reduced.

### CROSS-REFERENCE TO RELATED APPLICATIONS

This application claims the benefit of co-pending provisional patent application Serial No. 60/386,773 entitled “Method to Reduce Ebeam—Magnetic Material Interactions”, filed on Jun. 6, 2002, the entire disclosure of which is incorporated by reference herein.

### FIELD OF THE INVENTION

The present invention is directed toward patterning magnetic materials and, more particularly, toward patterning magnetic materials on a nanometer scale.

### BACKGROUND OF THE INVENTION

As the areal densities of magnetic recording media continually increase, the physical size of the sensors and writers designed to read and write data from and to the magnetic media must decrease. It has been estimated that at an areal density of 1 Tb/in², the critical dimensions of both the sensor (read) and write poles will be on the order of 25 nm. In order to manufacture and pattern critical dimensions on this small scale, lithography techniques capable of creating extremely fine patterns are required. Such lithography techniques include, but are not limited to, electron beam (e-beam) lithography, X-ray lithography, UV lithography, extreme UV (EUV) lithography, etc.

E-beam lithography utilizes a beam of electrons to “write”, or pattern, features in an e-beam resist. The beam of electrons is defocused, rastered, and directed toward the e-beam resist via magnetic lenses. A problem arises, however, when e-beam lithography is utilized to pattern magnetic materials. The magnetic fields from the magnetic materials being patterned can deflect the electrons from their intended path, or may effect the lenses themselves possibly resulting in offset and distorted structures and patterns. If the offset or distortion is on the same order of magnitude as the critical dimension being patterned, operation of a resultant device formed therefrom can be detrimentally effected.

As shown in FIG. 1, electron beam lithography typically utilizes an e-beam write field 100 of approximately of 800 m². Typically, a beam of electrons is emitted from an electron gun 112 through magnetic, or electrostatic, lenses 114 which deflect the electron beam within the e-beam write field 100. Electrons are deflected according to the formula:

\overline{F}=e(\overline{v}×\overline{B}), (Eq. 1)

where \overline{F} is the force on the electron, e is the electron charge, \overline{v} is the velocity of the electron, and \overline{B} is the magnetic field applied by the electron lenses 114. In Eq. 1, \overline{F}, \overline{v}, and \overline{B} are vectors.

The final electrostatic lens 114′ is located approximately 1″ above the substrate surface. The electrostatic lenses 114 deflect the electron beam within the electron beam write field 100. At the nominal, or normal, deflection from the lenses 114, the electrons impinge at the center of the electron beam write field 100 normal to the substrate surface, as shown by path 116. The electrostatic lenses 114 are located directly in the center of the write field 100, and deflect the electron beam at various angles with respect to the substrate surface to write a preselect pattern within the e-beam write field 100. Regardless of the angle of incidence of the electron beam, the fields from the magnetic material in the film plane will deflect the beam. Problems arise, however, when a magnetic material is to be patterned and the electron beam is deflected by the lenses 114 at an angle other than normal to the substrate surface.

The present invention is directed toward overcoming one or more of the above-mentioned problems.

### SUMMARY OF THE INVENTION

A magnetic material structure is provided according to the present invention that is capable of being lithographically patterned for various uses, such as, magnetic read/write devices. However, the inventive structure is not limited to such uses. The magnetic material structure includes a layer of magnetic material provided on a wafer or other substrate, a layer of non-magnetic material provided on top of the layer of magnetic material, and a layer of soft magnetic material provided on top of the layer of non-magnetic material. The magnetic material which is to be patterned will have a magnetic field component normal to a plane of the layer of magnetic material. To minimize the effect this normal magnetic field component will have on electrons as they impinge the structure surface during e-beam lithography, the soft magnetic material has a high in-plane permeability sufficient to divert the magnetic material's normal magnetic field component into the plane of the layer of soft magnetic material. By “bending” the normal magnetic field component into the plane of the soft magnetic material layer, the normal magnetic field component will no longer interact with the electron beam and the e-beam offsets caused by such interaction are diminished.

In one form, the soft magnetic material includes NiFe (nickel-iron). However, the soft magnetic material layer may include any soft magnetic material having sufficient in-plane permeability properties to divert the normal magnetic field component of the magnetic material into the plane of the soft magnetic material layer. The non-magnetic material may include Ta (tantalum), or any other similar non-magnetic material.

A magnetic material structure capable of being lithographically patterned is also provided according to an alternate embodiment of the present invention. This alternate embodiment of the magnetic material structure includes a plurality of spaced apart magnetic pedestals of magnetic material provided on a wafer at select locations. Alumina (Al₂O₃) is provided on the wafer and fills the remaining areas of the wafer between the plurality of magnetic pedestals. The plurality of magnetic pedestals and the alumina are made substantially planar for ease of patterning devices on the magnetic material. Since excess magnetic material has been eliminated around the areas where devices will be patterned, there is a global reduction in the normal magnetic field component of the magnetic material. Accordingly, the e-beam offset caused by this normal magnetic component is reduced.

In one form of the alternate embodiment of the present invention, the plurality of magnetic pedestals occupy approximately 10% of the wafer surface, with the alumina occupying the remaining approximately 90%. However, other percentages are contemplated.

In another form of the alternate embodiment of the present invention, the magnetic pedestals each include a magnetic material layer, a non-magnetic material layer provided on top of the magnetic material layer, and a soft magnetic material layer provided on top of the nonmagnetic material layer. The soft magnetic material layer has a high in-plane permeability sufficient to divert the normal magnetic field component of the magnetic material layer into the plane of the soft magnetic material layer, thereby further reducing the effects of the normal magnetic field component on the beam of electrons during e-beam lithography.

Methods of making magnetic material structures capable of being lithographically patterned are also provided according to the present invention. In a first embodiment, the method includes the steps of providing a layer of magnetic material on a wafer, with the magnetic material having a magnetic field component normal to the plane of the magnetic material layer. A layer of non-magnetic material is provided on top of the magnetic material layer, with a layer of soft magnetic material provided on top of the non-magnetic material layer. The soft magnetic material has a high in-plane permeability sufficient to divert the normal magnetic field component of the magnetic material into the plane of the soft magnetic material layer, thereby reducing its effects on the electron beam during e-beam lithography patterning.

In one form of the first embodiment, the method further includes the steps of removing the material layers on the wafer where devices will not be patterned to form a plurality of spaced apart magnetic pedestals, and depositing alumina on the wafer filling the areas where the material layers have been removed.

In a second embodiment of the inventive method, the method generally includes the steps of providing a plurality of spaced apart magnetic pedestals of magnetic material on a wafer at select locations, and providing alumina on the wafer at the areas between the plurality of magnetic pedestals filling the remainder of the wafer. The plurality of spaced apart magnetic pedestals are formed by providing magnetic material over the entire wafer, protecting select locations of the magnetic material on the wafer where devices will be patterned, and removing the excess magnetic material not corresponding to the select locations from the wafer to form the plurality of spaced apart magnetic pedestals. Alumina is provided on the wafer by depositing alumina over the entire wafer, including over the plurality of spaced apart magnetic pedestals. The alumina is then chemical-mechanical polished to leave a thin layer of alumina over the plurality of spaced apart magnetic pedestals. A reactive ion beam etching process is then employed to remove the alumina over the plurality of spaced apart magnetic pedestals, such that the alumina and the plurality of magnetic pedestals have a substantially planar surface.

It is an aspect of the present invention to reduce the global magnetic field component perpendicular to the plane of the magnetic material layer being patterned.

It is a further aspect of the present invention to reduce the interactions between the electron beam and the magnetic material during electron beam lithography patterning of the magnetic material.

Other aspects and advantages of the present invention can be obtained from a study of the specification, the drawings, and the appended claims.

### BRIEF DESCRIPTION OF THE DRAWINGS

FIG. 1 is a partial schematic of a conventional e-beam write field;

FIG. 2 is a side view of a schematic of a magnetic material to be patterned illustrating the magnetic material normal magnetic field components;

FIG. 3 is an e-beam resist image illustrating an e-beam stitching error which occurred when attempting to pattern conventional magnetic material structures;

FIG. 4 is a top view of a conventional 150 mm wafer illustrating areas typically used for patterning devices;

FIG. 5 is a plot of inspection values versus cube number using the legend set out in FIG. 4, showing the offsets for the various cubes of FIG. 4 in attempting to pattern a conventional magnetic material structure;

FIG. 6 is a side view of a schematic of a magnetic material structure according to the present invention;

FIGS. 7-8 are side views of schematics of a magnetic material structure according to an alternate embodiment of the present invention;

FIG. 9 is a top view of an e-beam resist pattern at the wafer center illustrating the magnetic material structure of the alternate embodiment of the present invention;

FIG. 10 is an e-beam resist image illustrating an e-beam stitching error when patterning the magnetic material structure of the alternate embodiment of the present invention;

FIG. 11 is a side view of a schematic of an additional embodiment of the magnetic material structure according to the present invention; and

FIG. 12 is a side view of a schematic of yet a further embodiment of the magnetic material structure according to the present invention.

### DETAILED DESCRIPTION OF THE INVENTION

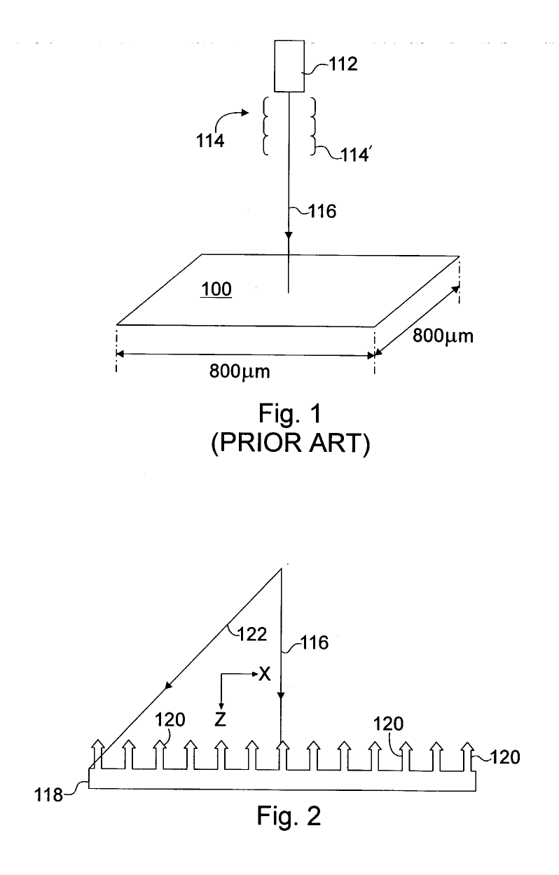

FIG. 2 illustrates a layer of magnetic material 118 to be patterned within an e-beam write field (100 in FIG. 1) using electron beam lithography techniques. For convenience, the electron gun 112 and the electrostatic lenses 114 have been omitted from FIG. 2. The magnetic material 118 includes a magnetic field component, shown at 120, which is substantially normal to a plane of the magnetic material layer 118. With the electrostatic lenses 114 in their steady state position, the electron beam is deflected down the center of the e-beam field and electrons impinge on the magnetic material 118 at the center of the write field, as shown by path 116. The velocity of the electrons along path 116 is entirely in the vertical or z direction. In this situation with the electrostatic lenses 114 in their steady state position, Eq. 1 is zero and no force due to the normal component of the field is applied to the beam of electrons. Although omitted from FIG. 2 for clarity purposes, an e-beam resist layer (not shown), as well as other non-magnetic and mask layers (not shown) will typically be provided on the magnetic material 118, with the e-beam resist layer provided on the top. E-beam lithography patterns the e-beam resist, and then known techniques are utilized to etch this pattern into the magnetic material layer 118.

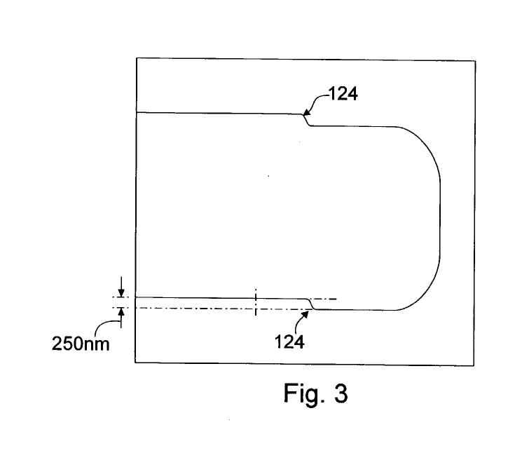

By controllably energizing the electrostatic lenses 114, the electron beam may be deflected over the entire surface area of the write field 100. One such path is shown at 122, and illustrates the electron beam deflected to the edge of the write field 100. Deflection of the electron beam to any point in the write field 100 other than at its center, as shown by the path 116, will cause the velocity of the electrons to have an x component. In these instances, there will be a finite cross product in Eq. 1 and, accordingly, a force exerted on the electrons by the perpendicular field component 120 of the magnetic material 118 and the x component of the electron velocity. The force exerted by the perpendicular field component 120 will act to offset or distort the electron beam from impinging on its targeted area within the write field 100. It has been found that this offset is a function of the location of the electron beam within the write field 100, and with no additional interactions gets larger toward to the edges of the write field 100. The image of FIG. 3 illustrates the offset caused by the interaction of the electron beam and the magnetic material normal magnetic field component 120.

FIG. 3 illustrates an image of an e-beam resist which has a measured offset, shown at 124, of 250 nm. The offset 124 occurs where two individual e-beam write fields 100 meet or overlap. The image at FIG. 3 is a classic example of what is commonly known in the art as an e-beam stitching error.

The e-beam stitching error shown in FIG. 3 occurred during e-beam lithography patterning of a perpendicular writer structure where a 3000 Å thick layer of iron-cobalt (Fe₆₅Co₃₅), a 4000 Å thick middle layer of tantalum (Ta), and a 500 Å thick top layer of nickeliron-chromium (NiFeCr) were deposited on an entire 150 mm wafer normally used for such patterning. The e-beam resist shown in FIG. 3 is provided on top of the NiFeCr layer in order to utilize electron beam lithography patterning techniques. The FeCo alloy in the above-described structure exhibits the highest known moment at room temperature and is commonly used in the production of magnetic recording heads. The FeCo alloy is magnetically isotropic and is not what is considered magnetically “soft”. Calculations have shown that a magnetic field component perpendicular to the plane of the magnetic material layer can have a magnitude on the order of the coercivity of the magnetic material itself. In the case of the above-described FeCo alloy, this coercivity is, at a minimum, 20 Oe. Thus, significant perpendicular fields can arise from the magnetic material itself and offset the electron beam as it impinges on the e-beam resist. As shown in FIG. 3, the offset caused by the perpendicular fields can be detrimental to patterning small features.

To complicate matters, the offset caused by the perpendicular fields of the magnetic material being patterned appear to be present on a global scale. In other words, the offset is not consistent from one write field to the next.

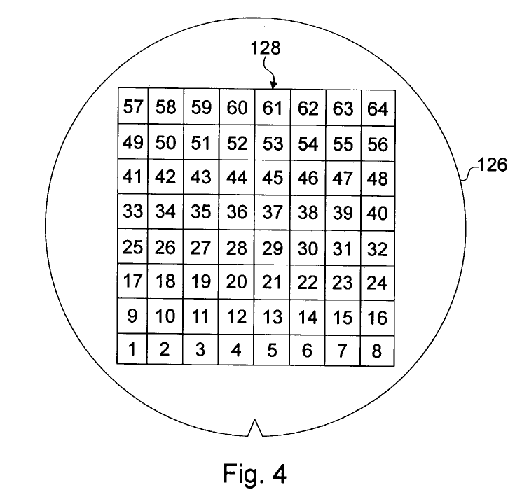

FIG. 4 illustrates a 150 mm wafer 126 typically utilized for the manufacture of magnetic reading and writing devices. While the entire surface of the wafer 126 is typically covered with a magnetic material to be patterned, only the cubed area 128 is actually utilized for the production of such devices. A plurality of e-beam write fields 100 may be provided in each of the cubes 1-64 within the area 128. As is common to e-beam lithography, once one write field has been patterned, the wafer 126 is moved to the center of the next write field and it is patterned. This continues until the entire area 128 on the wafer 126 is patterned. Typically, e-beam write fields are adjacent to one another and may overlap one another, and this overlap area is an area where e-beam stitching errors commonly occur. Thus, not only may there be offsets between adjacent cube areas, offsets may also occur within each cube area during e-beam lithography patterning of the magnetic material on the wafer 126.

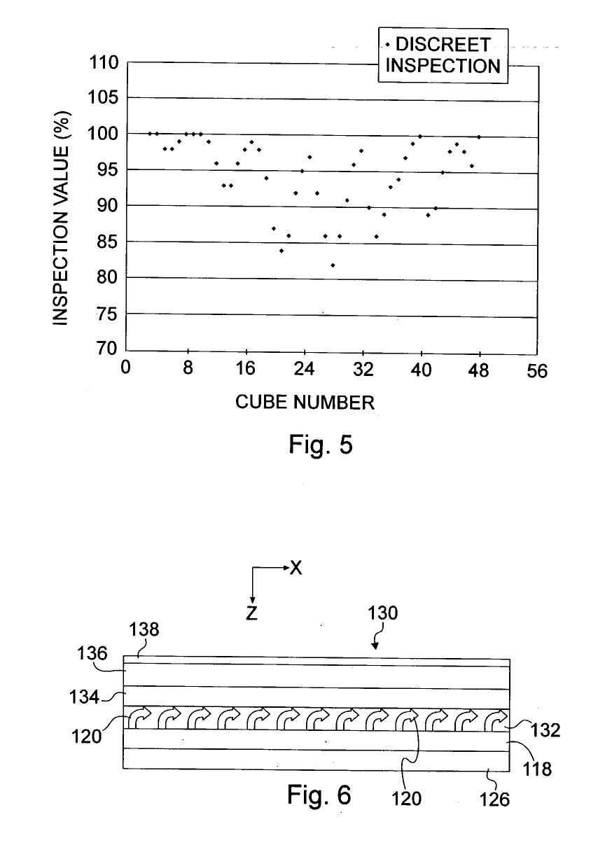

The plot of FIG. 5 illustrates discrete inspection values for the various cube areas 1-64 on the wafer 126. An inspection value of 100% indicates that no offset is present. The lower the inspection value, the larger the offset for that particular cube. The plot of FIG. 5 was generated utilizing the legend of cube area numbers shown in FIG. 4.

As shown in the plot of FIG. 5, offsets caused by the perpendicular field component of the magnetic material being patterned get much worse toward the center of the wafer 126. Additionally as shown in FIG. 5, the offset also worsens as you approach the center of a given row or column. For example, in comparing the offsets for cubes 1-8, FIG. 5 illustrates that the worst offset is in the center of the row, namely, at cubes 4 and 5. Additionally, cubes 28 and 29 were found to have larger offsets compared to cubes 4 and 5, respectively, even though they are in the same columns. The data shown in the plot of FIG. 5 suggests that the perpendicular magnetic field component of the magnetic material has a global effect on e-beam lithography patterning, and one that cannot be easily compensated for with current electron beam lithography systems

FIG. 6 illustrates a magnetic material structure, shown generally at 130, which reduces the offset caused by the perpendicular magnetic field component by shielding the perpendicular field component from the electron beam. The inventive structure 130 includes a layer of magnetic material 118 which is to be patterned within the e-beam write field 100. A layer of non-magnetic material 132 is provided on top of the magnetic material layer 118. A layer of soft magnetic material 134 is deposited on top of the non-magnetic material layer 132. An RIE (reactive ion etch) mask layer 136 is provided on top of the soft magnetic material layer 134, and a layer of conventional e-beam resist 138 is deposited on top of the RIE mask layer 136. Nickel-iron (NiFe) is contemplated as the soft magnetic material. NiFe with a composition of 80-20 (permalloy) exhibits a well-defined, in-plane uniaxial anisotropy resulting in a high in-plane permeability. As shown in FIG. 6, the high in-plane permeability of the NiFe layer 134 shields or bends the perpendicular field component 120 from the magnetic material 118 into the plane of the soft magnetic material 134 reducing its interaction with the electron beam. While NiFe is described herein as utilized for the soft magnetic material layer 134, any soft magnetic material having similar properties and a sufficient in-plane permeability to shield or bend the perpendicular field component 120 of the magnetic material 118 into the plane of the soft magnetic material layer 134 may be utilized without departing from the spirit and scope of the present invention. NiFe is listed herein for exemplary purposes only.

The structure 130 shown in FIG. 6 was built and the e-beam offset was measured. Specifically, the inventive structure 130 that was built included a 3000 Å thick magnetic material layer 118 of Fe₆₅Co₃₅, a 4000 Å thick non-magnetic material layer 132 of Ta, a 150 Å thick soft magnetic material layer 134 of NiFe, and a 350 Å thick RIE mask layer 136 of NiFeCr. The worst case offset measured with the inventive structure 130 was only 100 nm in the center of the wafer 126, as compared to the 250 nm offset (see FIG. 3) measured without the addition of the soft magnetic material layer 134. This is a factor of 2.5 improvement and, thus, the addition of the NiFe “shield” layer 136 can be added to diminish the e-beam offset caused by magnetic material perpendicular field components 120.

Since the NiFe layer 134 may be removed by an ion beam etching process similar to the NiFeCr layer 136, conventional electron beam lithography techniques may be utilized to pattern the magnetic material 118. For example, a desired patterned is formed in the e-beam resist 138 using conventional e-beam lithography techniques. The e-beam resist 138 may be either positive or negative tone with the usual behavioral properties, i.e., positive resists develop away at exposed regions, whereas in the case of negative resists the developed region remains behind after development. Thus, after developing the resist 138, a desired e-beam pattern is formed in the e-beam resist 138. Using a conventional ion beam etching process, the soft magnetic material layer 134 and the RIE mask layer 136 are removed at the patterned areas. Conventional reactive ion etching is utilized to remove the non-magnetic material layer 132 at the patterned areas. Then, an ion beam etching process is utilized to pattern the magnetic material 118, after which layers 132, 134, 136 and 138 are removed, leaving the patterned magnetic material 118.

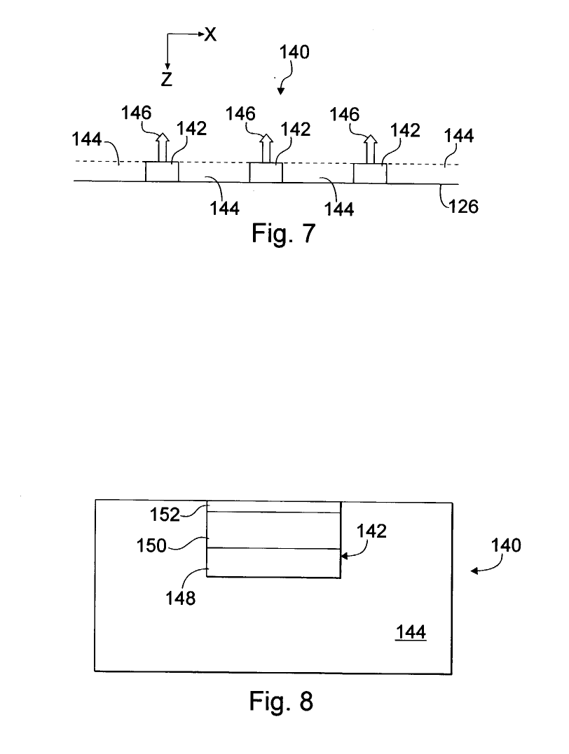

As shown by the data in FIG. 5, the e-beam offset is global and is dependent on wafer position, i.e., the e-beam offset is dependent upon the amount of magnetic material adjacent to the e-beam write field. FIGS. 7-8 illustrate a magnetic material structure in accordance with an alternate embodiment of the present invention which reduces the effect of the perpendicular field component on a global scale. The magnetic material structure, shown generally at 140, eliminates all of the excess magnetic material not needed to manufacture a device. The structure 140 includes a plurality of spaced apart magnetic pedestals of magnetic material 142 provided on the wafer 126 at select locations. The select locations are locations on the wafer 126 where devices are to be patterned. The remaining surface of the wafer 126 is filled with alumina (Al₂O₃) 144. Thus, while each of the magnetic pedestals 142 include a perpendicular magnetic field component 146, there are no perpendicular magnetic field components adjacent the magnetic pedestals 142, as the alumina 144 is non-magnetic. By reducing the perpendicular magnetic field components adjacent areas to be patterned, the e-beam offset can be reduced.

As shown in FIG. 8, each of the magnetic pedestals 142 includes a layer of magnetic material 148 (FeCo or other similar material), a layer of non-magnetic material 150 (Ta or other similar material), and an RIE mask layer 152 (NiFeCr or other similar material). For convenience, the e-beam resist has been omitted from FIGS. 7-8. The structure 140 shown in FIGS. 7 and 8 can be patterned using conventional e-beam lithography techniques, as previously described.

The structure 140 can be easily made in a “manufacturing” environment. The initial step is to deposit the magnetic and other materials which make-up the magnetic pedestals 142 (layers 148, 150 and 152) over the entire wafer 126. Optical lithography may then be employed to protect areas on the wafer 126 where devices will be patterned. The excess magnetic or other materials may then be removed by ion milling or other conventional techniques. The wafer 126 will now have a plurality of spaced apart magnetic “pedestals” everywhere on the wafer 126 that devices are to be patterned. Since e-beam lithography is to be used to pattern the pedestals 142, each of the pedestals will include a top layer of e-beam resist (not shown). Since e-beam resists tend to be thin and may have difficulty conforming to the tops of the pedestals 142 where devices are to be patterned, the structure 140 is made relatively planar. Alumina 144 is deposited everywhere on the wafer 126, including on top of the magnetic pedestals 142. Chemical-mechanical polishing is then employed to remove most of the alumina 144 and leave a very thin layer of alumina 144 over the magnetic pedestals 142. A trifluoromethane reactive ion beam etching process may then be utilized to remove the alumina 144 over the magnetic pedestals 142, such that the surfaces of the alumina 144 and the magnetic pedestals 142 are substantially planar.

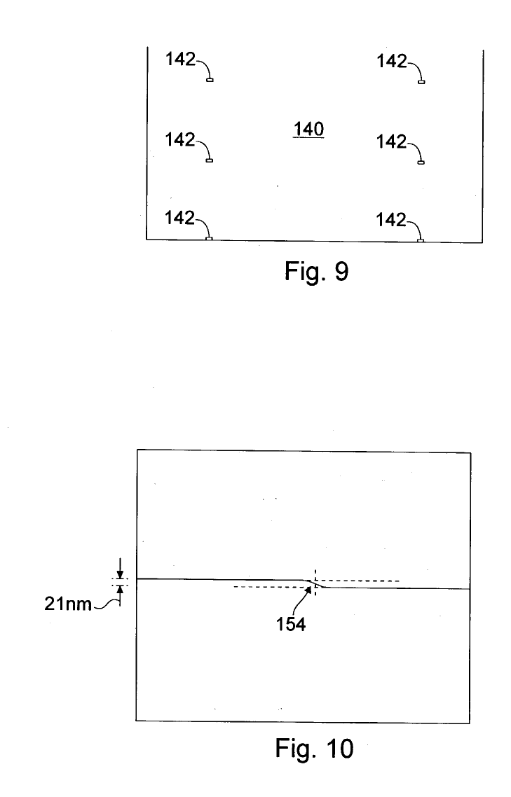

FIG. 9 shows the magnetic pedestal pattern at the wafer 126 center after the above-identified process has formed the magnetic material structure 140. As shown in FIG. 9, the small rectangles of the magnetic pedestals 142 are the only areas of magnetic material left on the wafer 126. These rectangles of magnetic pedestals 142 are the only areas where devices to be patterned will be located and, in the present example, only occupy approximately 10% of the wafer 126 surface, with the remaining approximately 90% of the wafer 126 surface being alumina 144. Thus, approximately 90% of the magnetic material resulting in e-beam deflections has been removed from the structure 140. It should be noted that these percentages are for exemplary purposes only, and other percentages may be utilized without departing from the spirit and scope of the present invention.

In one example, the rectangular magnetic pedestals 142 were made 36×21 μm² and include the 3000 Å thick layer of Fe₆₅Co₃₅ (layer 148), the 4000 Å thick layer of Ta (layer 150), and the 500 Å thick layer of NiFeCr (layer 152) which were previously shown to result in 250 nm offsets when provided over the entire wafer 126 surface. The image of FIG. 10 illustrates the offset in the e-beam resist pattern at the wafer 126 center utilizing the structure 140 previously described. As shown in FIG. 10, the worst offset, shown at 154, is approximately 21 nm, which is an improvement by a factor of approximately 12. This improvement is accomplished by removing excess magnetic material which is not necessary for the devices prior to e-beam lithography patterning.

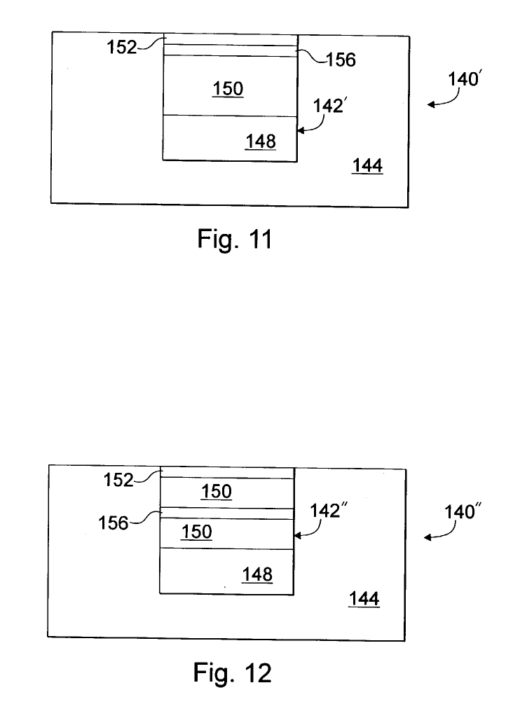

Two inventive solutions have been described herein which can reduce e-beam interactions with magnetic materials. A third such solution would be a combination of the two. By combining the two inventive solutions, the improvements that result from removing excess magnetic material not necessary for the patterning of devices, and from shielding the perpendicular field components of the magnetic material from the electron beams could be realized. An example of such a combination is illustrated in FIG. 11.

As shown in FIG. 11, the magnetic material structure 140′ includes a layer 156 of soft magnetic material (NiFe) provided between the non-magnetic material layer 150 (Ta) and the RIE mask layer 152 (NiFeCr). The soft magnetic material layer 156 has a high in-plane permeability sufficient to divert the normal magnetic field component 146 of the magnetic material layer 148 into the plane of the soft magnetic material layer 156. All excess magnetic material on the wafer 126 is milled away in a manner as previously described, leaving a plurality of spaced apart magnetic pedestals 142′ on the wafer 126 at select location where devices are to be patterned. In the structure 140′ shown in FIG. 11, the NiFe layer 156 and the NiFeCr layer 152 are utilized in combination as an RIE metal mask.

In an alternate embodiment, the NiFe layer 156 could be incorporated within the nonmagnetic layer 150, as shown in FIG. 12. The magnetic material structure 140″ shown in FIG. 12 incorporates the NiFe layer 156 within the layer of Ta 150 to form the magnetic pedestals 142″. The magnetic material structure 140″ would simply require an additional ion beam etching process to remove the NiFe layer 156 provided between the Ta layers 150, and an additional reactive ion beam etching process to remove the Ta layer 150 below the NiFe layer 156.

While the present invention has been described with particular reference to the drawings, it should be understood that various modifications could be made without departing from the spirit and scope of the present invention. For example, while specific materials have been described herein for the magnetic material (FeCo), non-magnetic material (Ta), soft magnetic material (NiFe), and RIE metal mask (NiFeCr) layers, these materials are identified for exemplary purposes only and one skilled in the art will appreciate that other materials having similar properties may be substituted therefore without departing from the spirit and scope of the present invention. Additionally, while the magnetic material being patterned has been described for use as magnetic read/write devices, this is for exemplary purposes only and the patterned magnetic materials may be utilized for any purpose without departing from the spirit and scope of the present invention.

We claim:

1. A magnetic material structure capable of being lithographically patterned, the magnetic material structure comprising:
a layer of magnetic material provided on a wafer, the magnetic material having a magnetic field component normal to a plane of the layer of magnetic material;
a layer of non-magnetic material provided on top of the layer of magnetic material; and
a layer of soft magnetic material provided on top of the layer of non-magnetic material, the soft magnetic material having a high in-plane permeability sufficient to divert the normal magnetic field component of the magnetic material into a plane of the layer of soft magnetic material.

2. The magnetic material structure of claim 1, wherein the magnetic material comprises FeCo.

3. The magnetic material structure of claim 1, wherein the non-magnetic material comprises Ta.

4. The magnetic material structure of claim 1, wherein the soft magnetic material comprises NiFe.

5. A magnetic material structure capable of being lithographically patterned, the magnetic material structure comprising:
a plurality of spaced apart magnetic pedestals of magnetic material provided on a wafer at select locations; and
alumina provided on the wafer at areas between the plurality of magnetic pedestals, wherein the alumina and the plurality of magnetic pedestals have substantially planar surfaces.

6. The magnetic material structure of claim 5, wherein the plurality of magnetic pedestals occupy approximately ten percent of the wafer surface.

7. The magnetic material structure of claim 5, wherein the magnetic material comprises FeCo.

8. The magnetic material structure of claim 5, wherein the plurality of magnetic pedestals each comprise:
a magnetic material layer having a magnetic field component normal to a plane of the magnetic material layer;
a non-magnetic material layer provided on top of the magnetic material layer; and
a soft magnetic material layer provided on top of the non-magnetic material layer, the soft magnetic material layer having a high in-plane permeability sufficient to divert the normal magnetic field component of the magnetic material into a plane of the soft magnetic material layer.

9. The magnetic material structure of claim 8, wherein the non-magnetic material comprises Ta.

10. The magnetic material structure of claim 8, wherein the soft magnetic material comprises NiFe.

11. A method of making a magnetic material structure capable of being lithographically patterned, the method comprising the steps of:
providing a layer of magnetic material on a wafer, the magnetic material having a magnetic field component normal to a plane of the magnetic material layer;
providing a layer of non-magnetic material on top of the magnetic material layer; and
providing a layer of soft magnetic material on top of the non-magnetic material layer, the soft magnetic material having a high in-plane permeability sufficient to divert the normal magnetic field component of the magnetic material into a plane of the soft magnetic material layer.

12. The method of claim 11, further comprising the step of patterning the magnetic material layer using electron beam lithography techniques.

13. The method of claim 11, wherein the magnetic material comprises FeCo.

14. The method of claim 11, wherein the non-magnetic material comprises Ta.

15. The method of claim 11, wherein the soft magnetic material comprises NiFe.

16. The method of claim 11, further comprising the steps of:
removing the material layers on the wafer where read/write devices will not be patterned to form a plurality of spaced apart magnetic pedestals each having layers of magnetic material, non-magnetic material, and soft magnetic material; and
depositing alumina on the wafer at areas where the material layers have been removed, wherein the alumina and the plurality of magnetic pedestals have substantially planar surfaces.

17. A method of making a magnetic material structure capable of being lithographically patterned, the method comprising the steps of:
providing a plurality of spaced apart magnetic pedestals of magnetic material on a wafer at select locations;
providing alumina on the wafer at areas between the plurality of magnetic pedestals, wherein the alumina and the plurality of magnetic pedestals have substantially planar surfaces.

18. The method of claim 17, wherein the step of providing the plurality of spaced apart magnetic pedestals comprises the steps of:
providing magnetic material over the entire wafer;
protecting select locations of the magnetic material; and
removing magnetic material not corresponding to the select locations from the wafer to form the plurality of spaced apart magnetic pedestals of magnetic material at the select locations.

19. The method of claim 17, wherein the step of providing alumina on the wafer comprises the steps of:
depositing alumina over the entire wafer, including over the plurality of spaced apart magnetic pedestals;
chemical-mechanical polishing the alumina to leave a thin layer of alumina over the plurality of spaced apart magnetic pedestals; and
employing a reactive ion beam etch to remove the alumina over the plurality of magnetic pedestals, such that the alumina and the plurality of magnetic pedestals have substantially planar surfaces.

20. The method of claim 17, further comprising the step of patterning the plurality of magnetic pedestals using electron beam lithography techniques.

21. The method of claim 17, wherein the magnetic material comprises FeCo.
